(19) United States
(12) Patent Application Publication
(10) Pub. No.: US 2014/0172334 A1
(43) Pub. Date: Jun. 19, 2014

(54) METHOD FOR CHARACTERIZATION OF ACCUMULATORS AND RELATED DEVICES

(71) Applicant: CALBATT S.R.L., Rende (CS) (IT)

(72) Inventors: Gregorio CAPPUCCINO, RENDE (CS) (IT); Francesco Antonio AMOROSO, RENDE (CS) (IT)

(73) Assignee: CALBATT S.R.L., Rende (CS) (IT)

(21) Appl. No.: 14/108,228

(22) Filed: Dec. 16, 2013

(30) Foreign Application Priority Data
Dec. 18, 2012 (IT) RM2012A000643

(51) Int. Cl. G01R 31/36

(52) U.S. Cl. CPC G01R 31/3627
USPC 702/63

(57) ABSTRACT

A method for characterization of the parameters of an equivalent model of an accumulator is described. The method is based on an accumulator equivalent circuit modelling primary and secondary chemical reactions. The method includes: a step of identification of the accumulator equivalent circuit; a step of characterization of the primary reactions during an accumulator charging process, wherein measurements of a given number of electric parameters of primary reactions branch in absence of secondary reactions are performed; a step of characterization of the secondary reactions during the charging process when also the secondary reactions are active; and a calculation step, that can be performed subsequently to the charging process, wherein mathematical functions allowing to extrapolate the values of the electric parameters in correspondence of a given state of charge are determined. A charging system, a charge control system, a computer and a storing device related to the method are also described.

### CROSS REFERENCE TO RELATED APPLICATIONS

The present application claims priority to Italian patent application RM2012A000643 filed on Dec. 18, 2012, which is incorporated herein by reference in its entirety.

### FIELD

The present disclosure relates to characterization of accumulators. Methods and related devices are disclosed herein.

### BACKGROUND

Energy accumulation systems based on batteries are being more and more utilized in a series of applications, such as for example storage of energy coming from intermittent renewable sources and propulsion of electric-driven vehicles.

In these applications, the charging process of the accumulators should be performed in an optimal way, continuously monitoring performances such as the state of charge (SOC) and the state of health (SOH) of the accumulator, and above all the energetic efficiency of the charging process, which is defined as the ratio between the energy actually stored by the accumulator and the energy overall supplied to the same during the charging process.

In this respect, even if the meanings of the two quantities are often confused, there is a substantial difference between the just described energetic efficiency and the coulombic efficiency, which is defined instead as the ratio between the charge actually stored into the accumulator and the one supplied altogether to the same accumulator during the charging process. Indeed, while the energetic efficiency is affected by all the causes of energy dissipation within a charging process, the coulombic efficiency is calculated by taking into account only the losses due to the secondary chemical reactions, that are those transforming the absorbed electric charge into electric charge accumulated at the terminals of the accumulator and available for a subsequent discharge process of the same accumulator (Berman et al., U.S. Pat. No. 4,001,036, Horn et al. U.S. Pat. No. 4,952,861, Ceraolo, “New Dynamical Models of Lead—Acid Batteries”), and that activate themselves during the charging processes of some types of accumulators (for example Lead, NiMH, NiCd) when the current supplied to the accumulator exceeds the maximum speed with which the primary chemical reactions can transform the supplied current into electric charge accumulated at the terminals of the accumulator.

For this reason, the charging methods aiming exclusively at maximizing the coulombic efficiency, avoiding the activation of the secondary reactions, do not automatically guarantee maximization of the energetic efficiency as well.

This can happen, for example, for some charging methods such as that proposed by Satake et al. (U.S. Pat. No. 6,246,216) wherein the charging current starts initially from a certain value and is progressively reduced when the activation of secondary reactions is detected.

Although in this case the losses due to secondary reactions are strongly reduced (one obtains a coulombic efficiency that this almost unitary), the lack of a precise knowledge of the remaining causes of energy dissipation entails an indetermination about the most suitable charging current value to be used in the initial phase of the charging process, wherein only the primary reactions are present, namely the chemical reactions transforming the absorbed charge into charge actually accumulated at the terminals of the accumulator and available for a subsequent discharge of the same accumulator.

From such indetermination, empirical criteria are often derived, which are extremely precautionary and which sometimes limit excessively both the initial charging current and the maximum voltage achievable by the accumulator during the charging process.

This can have negative consequences not only on the charging time, which obviously is remarkably slowed down by the use of low charging currents, but also on the overall energetic efficiency of the system, given that the battery chargers adopted usually tend to show a degradation of the efficiency for low levels of the output power.

In order to guarantee good performances, above all in terms of charging time and energetic efficiency, it is therefore important to abandon use of charging processes performed “blindly,” and provide for programmed charging on the basis of an accurate knowledge of all the characteristics of the specific accumulator used.

This can be performed in an efficient way by suitable mathematical models allowing to simulate the behavior of the accumulator and perform also useful predictions on the trend of the main physical quantities with varying operating conditions of the same accumulator during the charging process.

The characteristics of an accumulator are in general affected by ageing. Therefore, it is appropriate to use mathematical models whose parameters can be updated during the life of the same accumulator by means of an appropriate characterization process.

In order to guarantee the practical feasibility of the use of such models in actual applications, the above-mentioned process of characterization should actually be performable by means of a determined (possibly limited) number of measurements carried out on the field (i.e. when the accumulator is installed in the final system) in an automatic way, without the necessity to perform complicated lab tests and reducing down to the minimum the interruptions of service.

Hence, simulators based on physical-electrochemical models of the accumulator such as the one proposed by Notten et al. (U.S. Pat. No. 6,016,049) are generally unsuitable, given the great quantity of parameters of the model and the technical difficulty in performing a characterization process of such parameters on the field.

For the above described aims, it is instead more useful to resort to equivalent circuit models of the accumulator (Lin et al., US Pub. App. 2011/0309838), such as the one shown in FIG. 1.

In the model, a resistor R₀ 101 is responsible for the “instantaneous” variations of the voltage V_{B} 110 on the accumulator in the presence of variations of current I_{B} 105 flowing in the terminals of the same accumulator, and two R_{C} circuits (R₁-C₁ 102 and R₂-C₂ 103) that model different dynamic effects of the accumulator. The actual behavior of the accumulator could be well described by a different number of RC circuits with respect to those shown in the figure, without that, this limits in any way the general validity of what will be described in the following. The voltage generator with value V_{OC} 104 represents the open circuit voltage of the accumulator.

The current I_{acc} 106 indicates the current quantity actually supporting the primary chemical reactions within the accumulator which, as noted before, can differ from the current I_{B} during the charging process as a consequence of the phenomena connected to the secondary reactions, such as for example water electrolysis provoking the known phenomenon of gassing in the lead batteries.

These phenomena are modelled by the secondary branch 107 that absorbs a current I_{g} 108 describing the current absorption by the possible secondary reactions, and being in general function of the voltage V_{g} 109 at the terminals of the secondary branch.

In the following paragraphs, all the circuit elements of the model that are not part of the secondary branch (i.e. the elements through which current flows during the charging process also in presence of the only primary reactions) will be indicated as parameters of the primary branch. For the circuit of FIG. 1, the primary branch comprises R₀, R₁, C₁, R₂, C₂, and V_{OC}.

In general, the different parameters of the equivalent electrical model of the accumulator depend on the operating conditions of the same accumulator, in particular on the state of charge (SOC).

Hence, it is important to characterize the trend of parameters with varying SOC. To this end, a series of parameter measurements can be performed during a charging process, each time the state of charge is increased by a predetermined quantity.

In the state of the art, different methods have been proposed for the measurement of electric parameters of the accumulator. Some of them consist in the application of current waveforms to the accumulator and the evaluation of the corresponding time response of the voltage at its terminals. In particular, stopping the charging for a determined time period and evaluating the response of the voltage on the accumulator is convenient, as proposed for example by Denning (U.S. Pat. No. 7,095,211) and Paryani (US Pub. App. 2011/0077879) and illustrated in FIG. 2.

During such pause of the charging process a series of measurements of the voltage on the accumulator is performed, and from the interpolation of such measured values a function of the time response is obtained, which allows to extrapolate the steady state value of the open-circuit voltage V_{OC} in correspondence of the SOC value at hand. From such value of V_{OC} and the value of I_{B} as measured before the pause, the remaining parameters are determined by means of calculations carried out on the basis of the equivalent model of the accumulator. From the foregoing, the duration of the pause of the charging process should be such that an accurate estimation of the steady state value of the V_{OC} can be obtained.

The described approach offers good performances for estimation of the parameters of the primary branch in the absence of secondary reactions during the charging process. In these cases, indeed, the current I_{B} measured at the terminals of the accumulator is exactly equal to the current I_{acc} supporting the primary reactions (FIG. 1), therefore:
The increase of SOC for which the measurement phase is to be effected can be directly deduced by integrating the current I_{B} measurable at the terminals of the accumulator;
In order to determine the values of the parameters of the primary branch, it is sufficient to determine the values of V_{B} and I_{B} that are directly measurable at the terminals of the accumulator in correspondence of the application of the particular considered current waveform.

However, a different situation arises when secondary reactions are activated, because in such case considering I_{acc}=I_{B} for every scenario would introduce an error in the estimation of both SOC and the various parameters of the primary branch. Unfortunately, however, I_{acc} is not obviously determinable in such a direct way by means of current measurement at the terminals of the accumulator.

For such reason, it is important to first of all identify, during the charging process, the instant at which the secondary reactions are activated, i.e. the time instant at which the current I_{B} supplied to the accumulator exceeds the maximum current I_{acc} that can be absorbed by the primary electrochemical reaction. This is illustrated in FIG. 3, which shows the trends of the two currents in a normal two-steps, constant current-constant voltage (CC-CV) charging process and in which the time instant at which the secondary reactions activate is indicated with t_{g}.

In some methods, such as those proposed by Satake et al. (U.S. Pat. No. 6,198,254 and U.S. Pat. No. 6,246,216), such time instant is determined as the instant at which the voltage on the accumulator exceeds a certain threshold.

In fact, the instant t_{g} at which the secondary reactions are activated can be more correctly determined as the instant at which the time derivative of the voltage V_{B} on the accumulator undergoes a rapid variation (FIG. 4).

This has been discussed also by Kwok (U.S. Pat. No. 6,300,763), who has proposed a method wherein, once the time instant at which the secondary reactions are activated is determined, the current actually useful to the primary reactions I_{acc} is estimated according to a relationship connecting such a current to SOC, in order to determine the coulombic efficiency of the accumulator. However, as discussed in the foregoing, the energy losses due to the activation of the secondary reactions are not the only ones to be taken into account in order to determine the energetic efficiency, since a portion of the energy supplied to the accumulator during the charging process is dissipated on the resistors of the primary branch of the model, wherein the values are, by the way, heavily influenced by the activation of secondary reactions within the accumulator.

By way of example, reference can be made to the circuit in FIG. 1. In order to simplify the analysis, the capacitive components of the primary branch will not be considered (which assumption can typically be made in normal charging processes characterized by relatively slow voltage and current variations on the accumulator). In this case, the two resistors can be considered in series and can be replaced by a total equivalent resistor Rₜₒₜ=R₁+R₂.

The graph in FIG. 5 shows experimental data relevant to the trend of Rₜₒₜ as a function of SOC for a lead acid battery.

It is evident that the resistor has a rapid increase at the activation of secondary reactions, which comes out to be coherent with the decrease of the current I_{acc} useful to the primary reaction (FIG. 1).

In order to determine the impact of the secondary reactions on the parameters of the primary branch of the model, the two characterization methods discussed above could be combined, by simply estimating the activation instant of the secondary reactions and the current I_{acc} as a function of the state of charge, and by providing a series of interruptions of the charging process suitable to evaluate the time response of the voltage on the accumulator also during the phase wherein the secondary reactions are present.

However, such a solution could have a series of disadvantages.

First of all, experimental results show that the presence of secondary reactions extend significantly the minimum duration of each pause of the process needed for a correct estimation of the V_{OC} at operating speed.

Even more important is the fact that the activation instant of the secondary reactions, as well as the subsequent behavior of the accumulator in the presence of secondary reactions, depends on the current I_{B} used to charge the accumulator and the state of charge of the same accumulator at the beginning of the charging process.

This means that the possible parameters values, derived by means of the combination of the described methods into a charging process, characterized by a given initial value of SOC and a given charging current, would not allow an accurate estimation of the performances (and in particular the energetic efficiency) of the accumulator in correspondence of any other charging process carried out by starting from a different initial value of SOC and a different charging current.

In order to overcome this problem, one would need to apply the existent methods by carrying out m n charging cycles, wherein m represents the number of different charging currents that one wants to explore and n represents the number of different initial states of charge that one wants to explore.

In practice, such time-consuming procedure would be suitable to be possibly carried out only in the step of production of the accumulator, and not during the life of the same accumulator. Moreover, the values determined in such way could deviate from the real ones both for the inevitable ageing of the accumulator during its use and for the different conditions in which the accumulator would be used in practical applications.

For the given purpose, it is instead important to provide a rapid characterization method, which allows to obtain a good accuracy in the forecasts of the performances of the accumulator in all possible operating conditions by means of a low number of tests.

In view of the foregoing, it is not possible to obtain such method by means of a simple combination of the different existent state of the art methods as discussed above.

### SUMMARY

Embodiments of the present disclosure provide a method for characterization of parameters of the equivalent model of the accumulators, which allows to overcome the limits of the traditional methods. The present disclosure also provides means to perform such method.

According to a first aspect, a method for characterization of electric parameters of an equivalent circuit of an accumulator as a function of its state of charge is provided, the method comprising a step A.1 of identification of an equivalent electric model of the accumulator, a step A.2 of characterization of primary chemical reactions of the accumulator, a step A.3 of characterization of secondary chemical reactions of the accumulator, and a step A.4 of calculation of electric parameters, said steps being as follows:

A.1) defining an equivalent electric circuit characterized by a set of electric parameters, said circuit comprising at least one primary branch including elements that during a charging process are traversed by current even in presence of only primary chemical reactions of the accumulator and to which primary branch respective primary parameters Pᵢ are associated, i being a positive integer, and at least one secondary branch including elements that during a charging process are traversed by current only in presence of secondary chemical reactions of the accumulator and to which secondary branch respective secondary parameters are associated;
A.2) characterizing the primary parameters Pᵢ of the primary branch, by repetitively executing, during an initial step of at least one accumulator charging process wherein the secondary reactions are negligible, whenever the accumulator state of charge is incremented by a pre-determined quantity obtained by a measurement of a state of charge during an overall accumulator charging process, the following sub-steps:
A.2.1) applying to the accumulator a pre-determined current and/or voltage waveform;
A.2.2) measuring, during a time interval, a pre-determined number of voltage values at the terminals of the accumulator and/or values of current flowing into the accumulator;
A.2.3) interpolating said voltage and/or current values measured in step A.2.2, determining an interpolating function reconstructing a time response of the voltage or current on the accumulator as a consequence of application of said waveform, and from said function obtaining the values of the electrical parameters of said at least one primary branch,
thus obtaining a set of values for each primary parameter Pᵢ, and executing subsequently the following sub-step:
A.2.4) for each primary parameter Pᵢ of said at least one primary branch, determining, by interpolation of said set of values, a function linking the value of the parameter to the generic increment of state of charge during the charging process when only the primary reactions are active;
A.3) characterizing the parameters of the at least one secondary branch, by repetitively executing, during time instants subsequent to said initial step of at least one accumulator charging process, the following subsequent steps:
A.3.1) a testing step for testing presence of secondary reactions wherein, in a given instant, voltage and current at the accumulator terminals are measured, and presence of secondary reactions is determined if said voltage and current values deviate of a pre-determined quantity from the voltage and current values as calculated by means of the equivalent circuit of step A.1, assuming that the current absorbed in the at least one secondary branch vanishes and determining the parameters of the at least one primary branch by extrapolating the functions determined in step A.2.4, and storing: a first time instant t_{g} wherein the presence of secondary reaction is determined, current I_{B}(t_{g}) measured at the accumulator terminals at instant t_{g} and increment of state of charge ΔSOC(t_{g}) obtained from the beginning of the charging process up to time instant t_{g} as coming from the state of charge measurements of step A.2;
A.3.2) a sampling step wherein a pre-determined number of voltage and current values is stored at the accumulator terminals in correspondence of time instants subsequent to said time instant t_{g};
A.4) determining, in any time instant subsequent to the end of said step A.3, mathematical functions allowing to calculate, for a hypothetical charging process, the primary electrical parameters Pᵢ of the accumulator in correspondence of any value of the state of charge both in absence and in presence of secondary reactions, performing the following sub-steps:
A.4.1) determining, on the basis of a value of the initial state of charge SOC₀ of said at least one charging process and the values of t_{g}, I_{B}(t_{g}) and ΔSOC(t_{g}) stored in step A.3.1, a function I_{acc}(SOC), linking the maximum current I_{acc} that can be absorbed by the at least one primary branch and the state of charge SOC, that satisfies the condition:

I_{acc}[SOC₀+ΔSOC(t_{g})]=I_{B}(t_{g})

A.4.2) determining, on the basis of the function I_{acc}(SOC) and the accumulator equivalent circuit, the values of the voltage and current at the terminals of the at least one secondary branch in correspondence of the values of voltage and current at the terminals of the accumulator stored in step A.3.2, and, by interpolating such values, determining a function V_{g}(I_{g}) expressing the relationship between voltage V_{g} and current I_{g} at the terminals of the at least one secondary branch;
A.4.3) determining mathematical functions connecting primary parameters Pᵢ and the state of charge both in absence and in presence of secondary reactions, performing for each primary parameter Pᵢ the following sub-steps:
A.4.3.1) determining, by interpolation of the values of said set of values of the parameters referred of step A.2, an interpolating function fₚᵢ(SOC), expressing a relationship between the primary parameter Pᵢ and the state of charge when only the primary reactions are active, and
A.4.3.2) determining a function fₛᵢ(SOC) expressing a relationship between the primary parameter Pᵢ and the state of charge when also the secondary reactions are active, said function coinciding with fₚᵢ(SOC) if the value of the primary parameter Pᵢ as a function of SOC is not influenced by the presence of secondary reactions, said function being otherwise determined by circuit analysis on the basis of the accumulator equivalent electric circuit as defined in step A.1, the function I_{acc}(SOC), the function V_{g}(I_{g}) and the parameters whose function fₛᵢ(SOC) coincides with fₚᵢ(SOC).

The primary branch is, in particular, characterized by the interconnection of elements through which, during the charging process, the current flows also in the presence of the only reversible primary chemical reactions transforming the electric charge absorbed during a charging process into electric charge accumulated at the terminals of the accumulator and available for a subsequent discharge process of the accumulator.

The secondary branch is, in particular, characterized by the interconnection of circuit elements through which, during the charging process, the current flows only in the presence of irreversible secondary chemical reactions which do not transform the electric charge absorbed during the charging process into electric charge accumulated at the terminals of the accumulator and available for a subsequent discharging process of the accumulator.

In some situations, the above primary and secondary reactions are also indicated respectively as main and parasite reactions. Additionally, the details of their definition can vary in some way with respect to the definition given in the above description. However, the skilled person will recognize the general validity of the method, regardless of the definitions of the types of chemical reactions involved in the charging process. Indeed, the primary and secondary chemical reactions are modelled respectively in the primary and secondary branches of a circuit model of the accumulator and therefore can be specified each time, depending on the type of the accumulator and its behavior. It should be noted that the reactions producing charge accumulated and available for subsequent discharge should be distinguished from reactions that instead do not.

According to an aspect of the disclosure, the initial state of charge SOC₀ is not known before said at least one charging process, and in place of step A.4.1 the following step is executed:

A.4.1bis) determining the initial state of charge SOC₀ of said at least one charging process and a mathematical function I_{acc}(SOC) connecting the maximum current I_{acc} that can be absorbed by the at least one primary branch and the state of charge SOC, performing an iterative procedure comprising the following steps:
A.4.1.1) assuming a value of SOC₀;
A.4.1.2) on the basis of the assumed value of SOC₀ and the values of t_{g}, I_{B}(t_{g}) and ΔSOC(t_{g}) stored in step A.3.1, calculating a function I_{acc}(SOC) satisfying the condition:

I_{acc}[SOC₀+ΔSOC(t_{g})]=I_{B}(t_{g})
A.4.1.3) calculating the state of charge increment ΔSOC_{S} obtained by integrating the current I_{acc}, calculated according to the function determined in step A.4.1.2, from instant t_{g} up to a pre-determined instant of said at least one charging process of steps A.2 and A.3, and calculating the state of charge SOC_{f} of the charging process in said pre-determined instant, estimated on the basis of the following relationship:

SOC_{f}=SOC₀+ΔSOC(t_{g})+ΔSOC_{S}
A.4.1.4) calculating the difference between the state of charge actually achieved in said pre-determined instant of said at least one charging process and the state of charge SOC_{f} estimated in step A.4.1.3;
A.4.1.5) if the difference calculated in step A.4.1.4 exceeds a pre-determined quantity, increasing the assumed value of SOC₀ by a quantity that is function of said difference, in particular proportional to said difference, and repeating steps A.4.1.2-A.4.1.5, otherwise terminating the iterative procedure.

According to an aspect of the disclosure, for a pre-determined number of repetitions of step A.2.2 a first group of measurements is performed, wherein:
the duration of the time interval wherein each measurement is performed is such to allow the measurement of all the parameters of said at least one primary branch, and wherein the measured parameters values are also used to define mathematical functions expressing a subset of the parameters of said at least one primary branch as a function of a different subset of the parameters of said at least one primary branch assumed as set of reference parameters;
and wherein the remaining repetitions of step A.2.2 comprise a second group of measurements, wherein:
the duration of the time interval is such to allow only measurement of said reference parameters, and wherein the values of the remaining parameters of said at least one primary branch are obtained from the values of said reference parameters by extrapolation using the functions calculated during the first group of measurements.

Since the constants in the transient phase where the voltage or current waveform is applied to the accumulator have different observation times, the measurement time should be sufficiently long to measure all of them.

According to an aspect of the disclosure, function I_{acc}(SOC) is:

$${I}_{acc} = \frac{{A}_{0}}{1 - {SOC}_{i}} ( \frac{1}{SOC} - 1 ) ,$$

SOCᵢ being the initial state of charge of said hypothetical charging process, and A₀ being a real value constant coefficient, determined in step A.4.1 according to claim 1, or in step A.4.1bis in the method according to claim 2.

According to an aspect of the disclosure, function V_{g}(I_{g}) determined in step A.4.2 is:

$${V}_{g} = {V}_{g 0} + {a}_{1} \frac{{I}_{Bref}}{{I}_{B}} {I}_{g} + {{a}_{2} ( \frac{{I}_{Bref}}{{I}_{B}} )}^{2} {I}_{g}^{2} ,$$

during the time intervals of the process wherein the charging process is at constant current, i.e. wherein the charging system connected to the accumulator behaves as a current generator, I_{Bref} being a generic value of the current flowing through the accumulator terminals that is taken as a reference value, V_{g0}, a₁ and a₂ being real value constant coefficients determined by interpolation of at least three values of I_{g} and V_{g} obtained in step A.4.2, and instead function V_{g}(I_{g}) is of the type

$${V}_{g} = \frac{{I}_{g} - {q}_{g}}{{m}_{g}} ,$$

during the time intervals of the process wherein the charging process is at constant voltage, i.e. wherein the charging system connected to the accumulator behaves as a voltage generator, q_{g} and m_{g} being two real-value coefficients whose value takes into account the voltage applied to the accumulator during the specific time interval wherein the charging process is at constant voltage.

According to an aspect of the disclosure, the at least one primary branch of the accumulator equivalent circuit defined in step A.1 comprises a determined number of resistors and at least one voltage generator whose value V_{OC} models the open-circuit voltage of the accumulator.

According to an aspect of the disclosure, for each resistor belonging to the at least one primary branch of the accumulator equivalent circuit, the function fₚᵢ(SOC) determined in step A.4.3.1 is:

fₚᵢ=αm_{Ri0}(SOC−SOCᵢ)+Rᵢ₀,

SOCᵢ being the initial state of charge of said hypothetical charging process, m_{Ri0} and Rᵢ₀ being real-value constant coefficients determined by means of interpolation of at least two values of said resistor as measured in step A.2, and α being a coefficient whose value is determined each time for each charging process according to the relationship:

$$α = \frac{1}{{m}_{Ri 0}} \frac{{f}_{si} ( SOC ( {t}_{g} ) ) - {R}_{i 0}}{SOC ( {t}_{g} ) - {SOC}_{i}} ,$$

wherein t_{g} is the instant at which the secondary reactions start, determined as the instant at which the current I_{acc} equals the current I_{B} flowing through the accumulator terminals, SOC(t_{g}) is the value of the state of charge calculated at t_{g}, and fₛᵢ(SOC(t_{g})) is the value of the function fₛᵢ(SOC), as determined in step A.4.3.2, calculated in correspondence of said value of SOC(t_{g}).

According to an aspect of the disclosure, function fₚᵢ(SOC) as determined in step A.4.3.1 and function fₛᵢ(SOC) as determined in step A.4.3.2 for the voltage generator of value V_{OC} coincide and are of the type:

fₚᵢ(SOC)=fₛᵢ(SOC)=m_{V}SOC+q_{V},

mᵥ and qᵥ being real-value constant coefficients determined by interpolation of at least two values of V_{OC} determined in step A.2.

According to an aspect of the disclosure, steps A.2 and A.3 are performed in correspondence to a given number of accumulator working temperature T to the end of characterizing the parameters of the accumulator equivalent circuit even as a function of the working temperature, determining in step A.4, by interpolation of the measured values:
a function I_{acc}(SOC, T) expressing the relationship between the maximum current that can be absorbed by the at least one primary branch and any values pair (SOC,T), and a function V_{g}(I_{g}, T) expressing the relationship between the voltage at the terminals of the at least one secondary branch and any values pair (I_{g}, T),
   and, for each parameter of the at least one primary branch, determining:
a function fₚᵢ(SOC, T), each time different depending on the parameter Pᵢ, that expresses the relationship between the parameter and any values pair (SOC,T) when only the primary reactions are active, and a function fₛᵢ(SOC,T), each time different depending on the parameter Pᵢ, expressing the relationship between the parameter and any values pair (SOC,T) when also the secondary reactions are active, such a function fₛᵢ(SOC,T) coinciding with fₚᵢ(SOC,T) if the value of the parameter as a function of (SOC,T) is not influenced by the presence of secondary reactions, otherwise being determined by circuit analysis on the basis of the accumulator equivalent circuit, the functions I_{acc}(SOC,T), V_{g}(I_{g}, T) and the parameters whose function fₛᵢ(SOC,T) coincides with fₚᵢ(SOC,T).

According to a further aspect of the disclosure, a charging system for electric energy accumulators is disclosed, such system being provided with an input section and an output section and being able to take energy from a source by the input section and to give energy to the accumulator by the output section, the system comprising the following elements:
a power section, suitable to provide electric energy to the accumulator and to apply to the same accumulator pre-determined voltage and/or current waveforms,
a voltage measurement device for measuring voltage at the terminals of the accumulator,
a current measurement device for measuring current flowing into the terminals of the accumulator,
a memory device, and
an electronic calculation device,
   said system being suitable to perform any charging process of the accumulator and the method of characterization of the electric parameters of the electric equivalent circuit according to the method according to the present disclosure, wherein:
said power section is configured to apply to the accumulator a current and/or voltage waveform according to step A.2.1;
said voltage measurement device and said current measurement device are configured to perform the measurements of steps A.2.2, A.3.1, A.3.2;
said calculation device perform the calculations of steps A.2, A.3 and A.4;
said memory device is used to store the data calculated by the method.

A further aspect of the present disclosure deals with a charge control system for an electric energy accumulator receiving energy from an external battery charger, which includes an input section and an output section and is able to take energy from a source by the input section and to give energy to the accumulator by the output section having two terminals, said charge control system comprising two control terminals suitable to be connected, directly or by means of one or more devices in series, at the two terminals of said output section of the battery charger, and further comprising:
a load device suitable to absorb electric current by said two control terminals;
a voltage measurement device for measuring the voltage at the terminals of the accumulator;
a current measurement device for measuring the current flowing into the accumulator terminals,
a memory device, and
a calculation device,
   said system being suitable to execute the method of characterization of the electrical parameters of the accumulator electric equivalent circuit according to the method of the present disclosure, wherein:
said load device is configured to absorb electric current by said two control terminals during pre-defined time intervals in such a way that a pre-defined current and/or voltage waveform is applied to the accumulator, according to step A.2.1;
said voltage measurement device and said current measurement device are configured to perform the measurements of steps A.2.2, A.3.1, A.3.2;
said calculation device performs the calculations of steps A.2, A.3 and A.4; said memory device is configured to store the data calculated in the method.

Although both of the just described systems are able to implement the discussed method of characterization, there is a difference in terms of functionality between the charging control system and the charging system as described above. Indeed, the charging system is also able to implement a charging process of the accumulator by taking out energy from the source and giving it to the same accumulator. Such functionality is not guaranteed in the charging control system, which is instead understood as an additional device suitable to be connected to the terminals of a battery charger used to perform the charging process of the accumulator.

According to an aspect of the disclosure, the system further comprises at least one switching block connected in series between the terminals of the output section of the battery charger and the accumulator terminals, the switching block being configured to electrically disconnect the accumulator from the output section of the battery charger during the time intervals wherein the load device absorb current, and to electrically connect the accumulator to the output section of the battery charger in the remaining time intervals.

Presence of electric connection can be implemented in several different ways, such as insertion of:
switches that physically disconnect two circuit portions;
devices that do not disconnect physically the two portions of the circuit, but create a situation of “high impedance”, interrupting current passage.

According to an aspect of the disclosure, the system also comprises the following elements:
a voltage generator provided with two terminals suitable to be electrically connected, directly or by one or more devices in series, to the terminals of the output section of the battery charger, said voltage generator being suitable to establish a voltage difference between its terminals;
at least one switching block connected in series between the terminals of said voltage generator and the terminals of the output section of the battery charger, such switching block being configured to electrically connect the voltage generator to the output section of the battery charger during the time intervals wherein the load device absorbs current, and to electrically disconnect the voltage generator from the output section of the battery charger in the remaining time intervals.

According to an aspect of the disclosure, the system further comprises a power section suitable to supply current by said two control terminals.

A computer device comprising a processor, the processor configured to execute instructions of a computer program that performs the calculations of steps A.2, A.3 and A.4 of the above described method is provided.

In accordance with a further aspect of the disclosure, a non-transitory memory support, storing a computer program that performs, when executed on a computer, the calculations of steps A.2, A.3 and A.4 of the method is also provided.

### BRIEF DESCRIPTION OF THE DRAWINGS

The invention will be now described by way of illustration but not of limitation, with reference to the drawings of the enclosed figures, wherein:

FIG. 1 shows an equivalent circuit model of the accumulator;

FIG. 2 shows a time response of the voltage on the accumulator to a current step;

FIG. 3 shows a trend of I_{acc} and I_{B} in a CC-CV process;

FIG. 4 shows a time trend of the voltage on the accumulator;

FIG. 5 shows a trend of Rₜₒₜ as a function of SOC;

FIG. 6 shows a characterization procedure with two measurements steps of different duration;

FIG. 7 shows a relationship between I_{g} and V_{g} in the CC and CV charging phases;

FIG. 8 shows a flow chart summarizing a possible implementation of the proposed characterization method according to the present disclosure;

FIG. 9 shows a possible implementation of the charging system implementing the method proposed according to the present disclosure;

FIG. 10 shows a possible implementation of the charge control system proposed according to the present disclosure;

FIG. 11 shows a possible implementation of the charge control system comprising also a voltage generator, according to the present disclosure.

### DETAILED DESCRIPTION

A method for characterization of parameters of an equivalent model of an accumulator and related devices will be described.

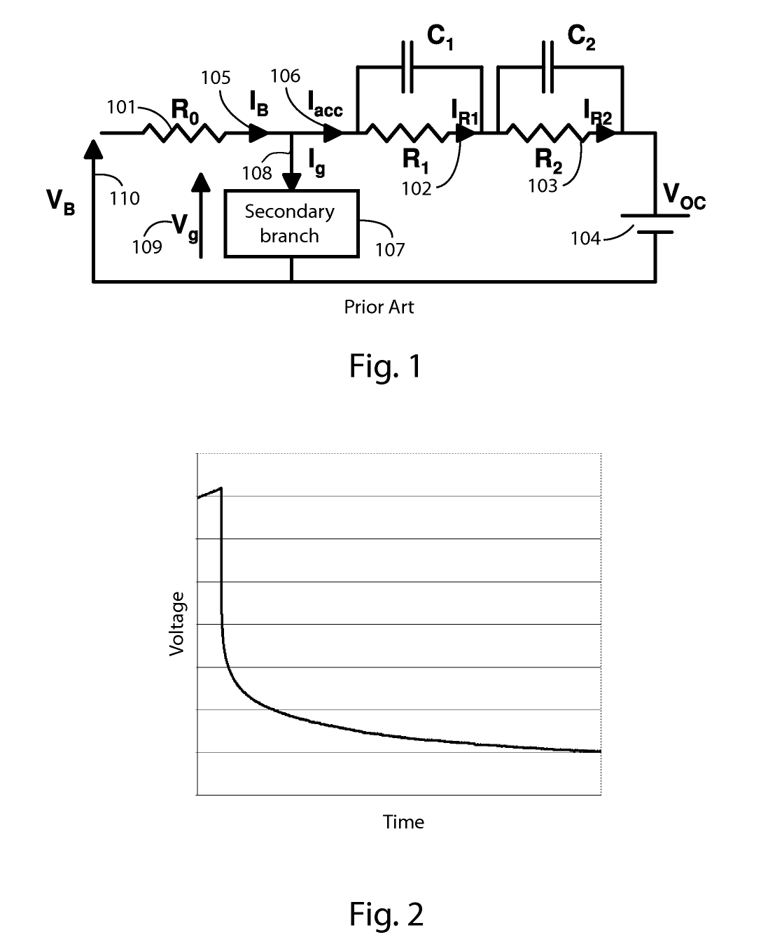

The method is based on the description of the accumulator by means of a suitable circuit model, such as that shown in FIG. 1. The circuit model is, in general, characterized by at least one primary branch, in the components of which the current flows even in absence of secondary reactions, and by at least one secondary branch in the component of which current flows only in presence of secondary reactions.

As explained above, the parameters of the model depend on the operating conditions of the accumulator, in particular on the state of charge (SOC). In order to be able to simulate the behavior of the accumulator, it is therefore appropriate to determine the mathematical functions that allow to calculate the values of the parameters with varying state of charge.

A method of characterization of the above electric parameters is provided, which allows to determine such functions.

The proposed method includes four main steps:
a step of identification of the equivalent model of the accumulator;
a step of characterization of the primary reactions, carried out during at least one charging process of the accumulator wherein measurements of a given number of electric parameters of the primary branch in the absence of secondary reactions are performed;
a step of characterization of the secondary reactions, carried out during the above charging process when also the secondary reactions are activated;
a calculation step, which can be performed at any moment subsequent to the above charging process, wherein mathematical functions are determined to allow extrapolation of the values of the electric parameters in correspondence of a determined state of charge, both in absence and in presence of secondary reactions.

The identification step of the equivalent model of the accumulator includes the definition of an equivalent electric circuit, characterized by a set of electric parameters with which it is possible to model the behavior of the accumulator, the circuit including:
at least one primary branch, characterized by the interconnection of circuit elements in which, during a charging process, the current flows also in the presence of the only primary chemical reactions which produce charge accumulation at the terminals of the accumulator;
at least one secondary branch, characterized by the interconnection of circuit elements in which, during the charging process, the current flows only in the presence of secondary chemical reactions that do not produce charge accumulation at the terminals of the accumulator.

Once the circuit model of the accumulator is defined, the steps of characterization of the primary reactions are executed, which can be performed as explained above by providing a given number of measurements steps, wherein a determined current and voltage waveform is applied to the accumulator (for example, the charging current of the accumulator is fixed to 0) and the electric parameters of the primary branch are determined.

Since the parameters vary with the SOC, it is appropriate to perform out the above operation in correspondence of a determined number of different values of SOC.

Once such measurements are performed, the values of the measured parameters are interpolated to obtain the mathematical functions which allow to extrapolate the value of the parameters of the branches of the primary reactions for any increment of SOC before the activation of the secondary reactions.

Since the above measurements are performed only when the primary reaction is activated, the increment of SOC from the beginning of the charge can, for example, be estimated simply by counting the charge introduced in the accumulator (coulomb counting).

On the basis of the above description, the steps of characterization of the primary reactions include the performing of the following sub-steps each time the state of charge of the accumulator is increased by a predetermined quantity before the activation of the secondary reaction:
applying a predetermined current and/or voltage waveform to the accumulator;
measuring, within a time interval, a given number of voltage values at the terminals of the accumulator and/or current flowing in the accumulator;
interpolating the above measured voltage and/or current values, determining an interpolating function that reconstructs the time response of the voltage or the current on the accumulator as a consequence of the application of the above mentioned waveform, and, from such function, obtaining the values of the electric parameters of the primary branch in correspondence of the SOC increments at which the above sub-steps are performed;
determining, by integration of the above mentioned measured values of the parameters of the primary branch, mathematical functions that allow to extrapolate such parameters for any increment of state of charge before the activation of the secondary reactions during the charging process.

The measurement of the whole set of electric parameters by means of the time response of the voltage on the accumulator to a current step can be a relatively slow operation, as there is a need to wait for a time sufficient (sometimes of the order of tens of minutes) to allow the relaxing of the voltage on the accumulator (FIG. 2).

Fortunately, for some types of currently used accumulators, in presence of the only primary reactions, the relationships between the parameters of the accumulator and the state of charge can be well described by linear functions, which therefore can be calculated on the basis of only two measurements in correspondence of two different SOC values.

Moreover, in order to reduce, down to the minimum, the waste of time during the charging process where the characterization is performed, it is also possible to resort to a particular solution, which provides two different groups of measurements:
a first group of measurements, whose duration is such to allow the measurement of all the parameters of the branches of the primary reactions, wherein the measured values of the parameters are also used to define mathematical functions allowing to express a determined number of parameters in the primary branch as a function of a determined subset of parameters, selected among all the parameters of the primary branch and assumed as reference parameters;
a second group of measurements of reduced duration, whose duration is such to allow only the measurement of the above-mentioned reference parameters, and wherein the remaining parameters of the primary branch are obtained by extrapolation, by using the values of the reference parameters as measured during the measurements belonging to such second group and the functions calculated during the above first type of measurements.

For example, with reference to the model of FIG. 1, it can be typically assumed that the time constant R₂C₂ is significantly larger than R₁C₁. Hence, the estimation of the parameters of the R₂-C₂ circuit extends the necessary minimum duration of the pauses performed during the charging process.

According to the above, in order to accelerate the characterization process, a first pause that is sufficiently long can be introduced, where all the model parameters and the functions connecting the components of the R₂-C₂ circuit to those of the R₁-C₁ circuit are determined, and a subsequent pause having duration shorter than the first one, where the values of R₀, R₁, and C₁ are determined, extrapolating from these the corresponding values of R₂, C₂, and V_{OC} on the basis of the previously calculated functions.

This is illustrated in FIG. 6, which shows two measurements steps of different duration during the step of characterization of the primary reactions.

After having performed the step of characterization of the primary reactions, a step of characterization of the secondary reactions is performed. As stated, in the presence of secondary reactions, a part of the current supplied to the accumulator is not useful to the charging of the same, but rather supports the secondary reactions at hand.

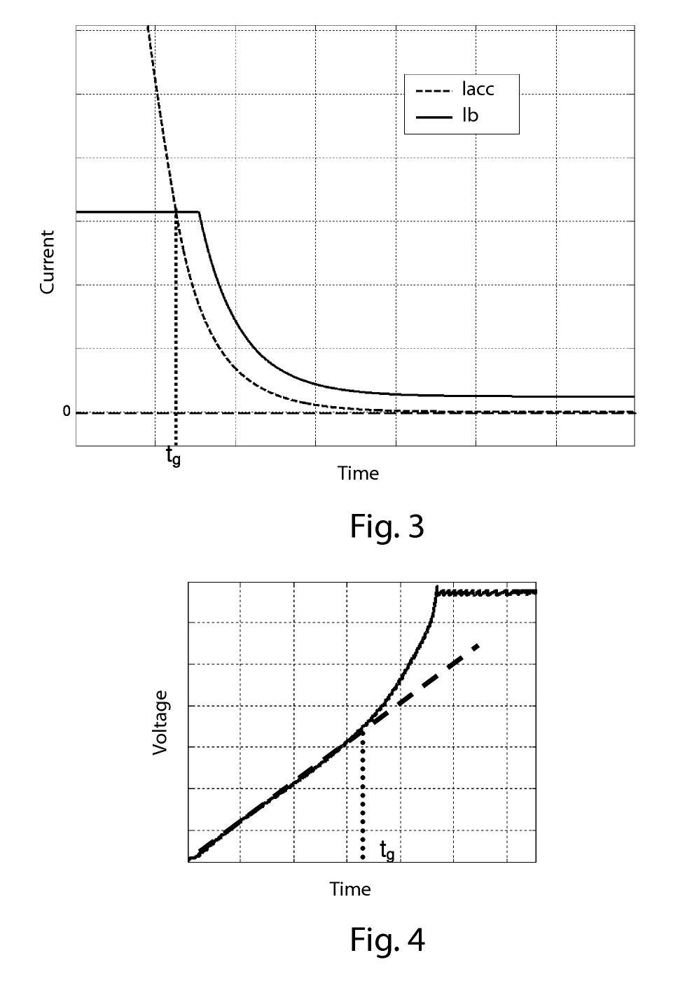

From an analytical point of view, it is possible to determine the instant t_{g} at which the secondary reactions are activated (FIG. 3 and FIG. 4), as well as the instant at which the voltage read on the accumulator differs of a predetermined quantity from the voltage estimated by using the equivalent model of the accumulator, whose parameters are calculated by using the mathematical functions determined in the characterization step of the primary reactions, and wherein the current I_{g} absorbed by each secondary branch is assumed equal to 0.

Since t_{g} is the instant at which the secondary reactions are activated, the total increment of SOC from the beginning of the charging up to t_{g} (ΔSOC(t_{g})) can be obtained directly by the counting of the charge introduced in the accumulator, but not after the activation of the secondary reactions.

Once t_{g} is determined, the end of the charging process is awaited, measuring and storing a determined number of values of voltage V_{B} as read at the terminals of the accumulator and the current I_{B} flowing in its terminals in correspondence of different time instants, among which instant t_{g} is present.

In general, it is also possible to provide for a further series of measurements of parameters of the primary reactions of the primary branch in this second step, taking into account in any case the difference between I_{acc} and I_{B}.

Therefore, in summary, the step of measurements in presence of secondary reactions comprises the following sub-steps:
determining the instant t_{g} at which the secondary reactions activate and the increment (ΔSOC(t_{g})) of the state of charge at the instant t_{g};
storing a determined number of values of voltage V_{B} and current I_{B} on the accumulator, including the voltage and current at the instant t_{g}.

After the two steps described above, the proposed method provides for a calculation step, comprising different sub-steps.

First of all, a function I_{acc}(SOC) allowing to calculate the current I_{acc} as a function of the state of charge is determined. Such function can be conveniently chosen to satisfy the following condition:

I_{acc}[SOC(t_{g})]=I_{B}(t_{g}), (1)

i.e. that at the instant t_{g} the maximum current that can be absorbed by the primary reactions is equal to the current I_{B} that flows at the terminals of the accumulator.

At this point, the state of charge of the accumulator at the instant t_{g} is given by the sum of the measured increment of state of charge (ΔSOC(t_{g})) and the state of charge SOC₀ that the accumulator had at the beginning of the characterizing charging process:

SOC(t_{g})=SOC₀+ΔSOC(t_{g}). (2)

In general, it is not necessarily true that SOC₀ is known in a precise way, therefore the proposed method provides a possible iterative step where the initial state of charge and the corresponding function I_{acc}(SOC) is determined. Such iterative step comprises the following steps:

1) Assuming a value of SOC₀;
2) Calculating a function I_{acc}(SOC) satisfying the condition:

I_{acc}[SOC₀+ΔSOC(t_{g})]=I_{B}(t_{g}) (3)

3) Calculating the estimated state of charge SOC_{f} in a predetermined instant of the charging process as:

SOC_{f}=SOC₀+ΔSOC(t_{g})+ΔSOC_{S}, (4)

ΔSOC_{S} being the increment of the state of charge as obtained by counting the charge accumulated by the accumulator from the time instant t_{g} to the above-mentioned predetermined time instant of the charging process by virtue of the only current I_{acc};
4) Calculating the difference between the state of charge that has been actually achieved in the above instant of the characterization charging process and the state of charge SOC_{f} as estimated in the previous step;
5) If the above difference exceeds a predetermined quantity, increasing the initial state of charge SOC₀ of a quantity that is function of the same difference (in particular proportional to such a difference) and repeating the steps 2)-4), otherwise exiting the iterative procedure.

Concerning the function I_{acc}(SOC), experimental results indicate that it can be conveniently expressed as follows:

$${I}_{acc} = \frac{{A}_{0}}{1 - {SOC}_{i}} ( \frac{1}{SOC} - 1 ) , \qquad ( 5 )$$

SOCᵢ being the initial state of charge of the charging process and A₀ being a real-values constant coefficient determined by the equation (1).

After having determined the trend of I_{acc}, it is possible to determine the relationship V_{g}(I_{g}) linking the voltage V_{g} and the current I_{g} at the terminals of the secondary branch. This relationship is obtained by interpolating the values of I_{g} and V_{g} that can be obtained by starting from the values of V_{B} and I_{B} stored during the measurement step in the presence of secondary reactions, taking into account the relationship I_{g}=I_{B}−I_{acc} of the circuit model of the accumulator.

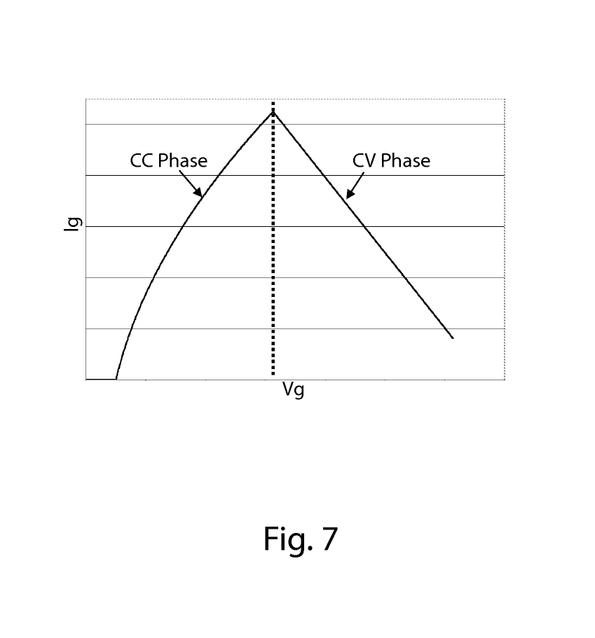

The relationship V_{g}(I_{g}) can have in general two different trends, depending whether the charging process of the accumulator is performed at constant current (CC) or constant voltage (CV). This is illustrated in FIG. 7 which shows the trend of I_{g} as a function of V_{g} for a generic of CC-CV charging process on a lead battery.

In particular, with reference such figure, a relationship V_{g}(I_{g}) that is quadratic in the CC step and linear in the CV step can conveniently be considered, according to the following equation:

$${V}_{g} = \{ \begin{matrix}{V}_{g 0} + {a}_{1} \frac{{I}_{Bref}}{{I}_{B}} {I}_{g} + {{a}_{2} ( \frac{{I}_{Bref}}{{I}_{B}} )}^{2} {I}_{g}^{2} , in step CC \\ \frac{{I}_{g} - {q}_{g}}{{m}_{g}} , in step CV\end{matrix} \qquad ( 6 )$$

wherein:
V_{g0}, a₁ and a₂ are real-values constant coefficients determined by interpolation of at least three values of I_{g} and V_{g} obtained by measuring at least three pairs (V_{B}, I_{B}) during the CC step of the charging process;
q_{g} and m_{g} are two real-values coefficients whose value can be determined each time by the determination of at least two pairs (V_{g}, I_{g}) calculated by the electric model of the accumulator;
I_{Bref} is a reference value of the current flowing in the terminals of the accumulator that can be chosen for example equal to a current value I_{B} as measured in the characterization charging process. The presence of I_{Bref} and I_{B} in the relationship V_{g}(I_{g}) models the fact that, in fact, the current I_{g} in a given instant has a value that is also connected to the current I_{B} flowing in that given instant in the accumulator.

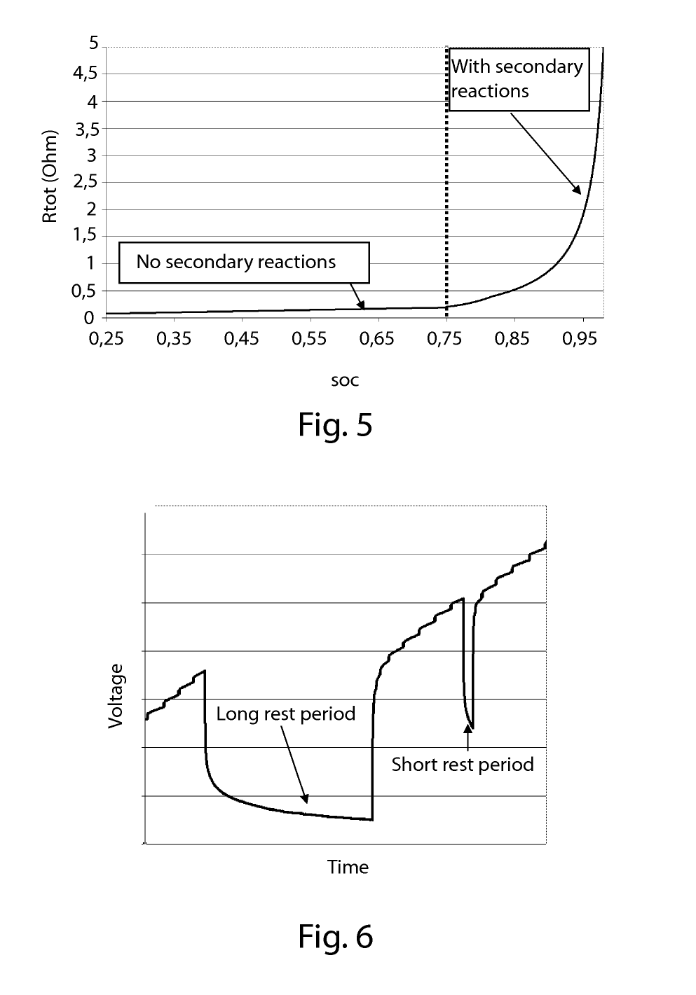

Once the initial state of charge SOC₀ of the characterization charging process and the functions for I_{acc} and V_{g}(I_{g}) for the parameters of the secondary branch are determined, the functions that express the parameters of the primary branch are determined. As stated above, such parameters can be affected in general by the presence of the secondary reactions (FIG. 5), and therefore two different functions are used expressing their trend as a function of SOC both in the absence and in the presence of secondary reactions.

For example, with reference to FIG. 5, the progression of the total resistance Rₜₒₜ as a function of SOC can be expressed by:
A first function, determined by the interpolation of the one or more values of Rₜₒₜ as measured during the step of characterization of the primary reactions, which expresses the relationship connecting Rₜₒₜ and SOC in the absence of secondary reactions;
a second function, which expresses the relationship connecting Rₜₒₜ and SOC in the presence of secondary reactions and derived in an indirect way by means of a circuit analysis based on the equivalent model of the accumulator and on the knowledge of the previously calculated functions I_{acc}(SOC) and V_{g}(I_{g}). With reference to the circuit of FIG. 1, and not considering the capacitors C₁ and C₂, such function can be written as follows:

$${R}_{TOT} ( SOC ) = \frac{{V}_{g} - {V}_{OC} ( SOC )}{{I}_{acc} ( SOC )} . \qquad ( 7 )$$

In general, the proposed method provides therefore for the definition of two different mathematical functions for each parameter P, of the primary branch:
a function fₚᵢ(SOC), each time different depending on the parameter, which expresses the relationship between the parameter and SOC when only the primary reactions are active, and is determined by interpolation of the one or more values of the parameters as measured during the step of characterization of the primary reactions;
a function fₛᵢ(SOC), each time different depending on the parameter, which expresses the relationship between the parameter and SOC when also the secondary reactions are active, such function coinciding with fₚᵢ(SOC) if the value of the parameter as a function of SOC is not influenced by the presence of the secondary reactions, otherwise being different from fₚᵢ(SOC), in the latter case being determined indirectly by a circuit analysis based on the electric model of the accumulator starting from the function I_{acc}(SOC), the function V_{g}(I_{g}) and the values of the parameters of the branches of the primary reactions, whose function fₛᵢ(SOC) coincides with fₚᵢ(SOC).

In some cases, as for the lead acid batteries, the functions fₚᵢ(SOC) can be linear.

For example, the function fₚᵢ(SOC) for the open-circuit voltage V_{OC} can be expressed as follows:

fₚᵢ(SOC)=fₛᵢ(SOC)=m_{V}SOC+q_{V}, (8)

wherein mᵥ and qᵥ are real constant-values coefficients that are determined by integration of the values of V_{OC} as measured during the step of characterization of the primary reactions. As shown by equation (8), fₛᵢ(SOC) coincides with fₚᵢ(SOC) because the trend of the open-circuit voltage as a function of the state of charge is not influenced by the presence of the secondary reactions.

Instead, for the resistors of the model, the functions fₚᵢ(SOC) can be expressed as follows:

fₚᵢ=αm_{Ri0}(SOC−SOCᵢ)+Rᵢ₀, (9)

wherein SOC, is the initial state of charge of the charging process, m_{Ri0} and Rᵢ₀ are real-values constant coefficients determined by interpolation of the resistors values determined in the step of characterization of the primary reactions, and

$$α = \frac{1}{{m}_{Ri 0}} \frac{{f}_{si} ( SOC ( {t}_{g} ) ) - {R}_{i 0}}{SOC ( {t}_{g} ) - {SOC}_{i}}$$

is a coefficient that can be determined each time for the particular charging process at hand on the basis of:
the value of the initial state of charge SOCᵢ;
the value of the state of charge SOC(t_{g}) at the time instant at which the secondary reaction activates, determined by circuit simulation as the instant at which the current I_{acc} equates the current I_{B} flowing in the terminals of the accumulator,
the value of the function fₛᵢ(SOC(t_{g})), determined by circuit simulation in correspondence of the value of state of charge SOC(t_{g}) at the instant t_{g}.

From a practical point of view, the coefficient α expresses a physical phenomenon by which the resistive components of the model of the lead acid batteries tend to show the same resistor value Rᵢ₀ at the beginning of the charging, irrespective of the initial state of charge SOCᵢ, and tend to increase linearly with a slope coefficient each time different depending on the current I_{B} flowing in the accumulator and SOCᵢ, such that the resistor value at the activation of the secondary reactions is equal to that calculated on the basis of the function fₛᵢ evaluated in correspondence of SOC(t_{g}).

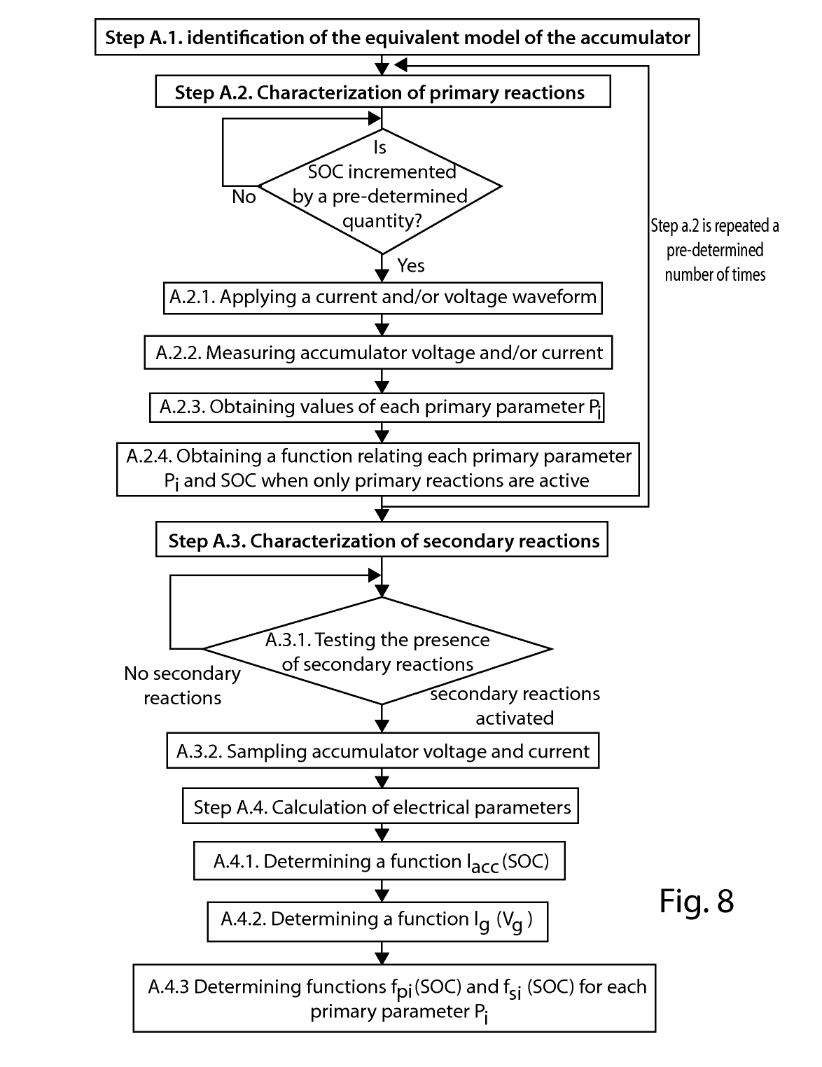

The flow chart of FIG. 8 schematizes the main steps of the proposed method according to one of the discussed embodiments.

Typically, the parameters of the accumulator show also a certain dependency on the working temperature. Therefore, according to another aspect of the present disclosure, the different steps of the above discussed method can be performed in correspondence of a determined number of different values of the system working temperature T (such measurements can be carried out within an only charging process, or possibly in a plurality of distinct charging processes). By interpolation of the measured values of the electric parameters of the branches of the primary and secondary reactions, the different above discussed functions can therefore be calculated in such a way to determine the different parameters of the model with varying state of charge and temperature.

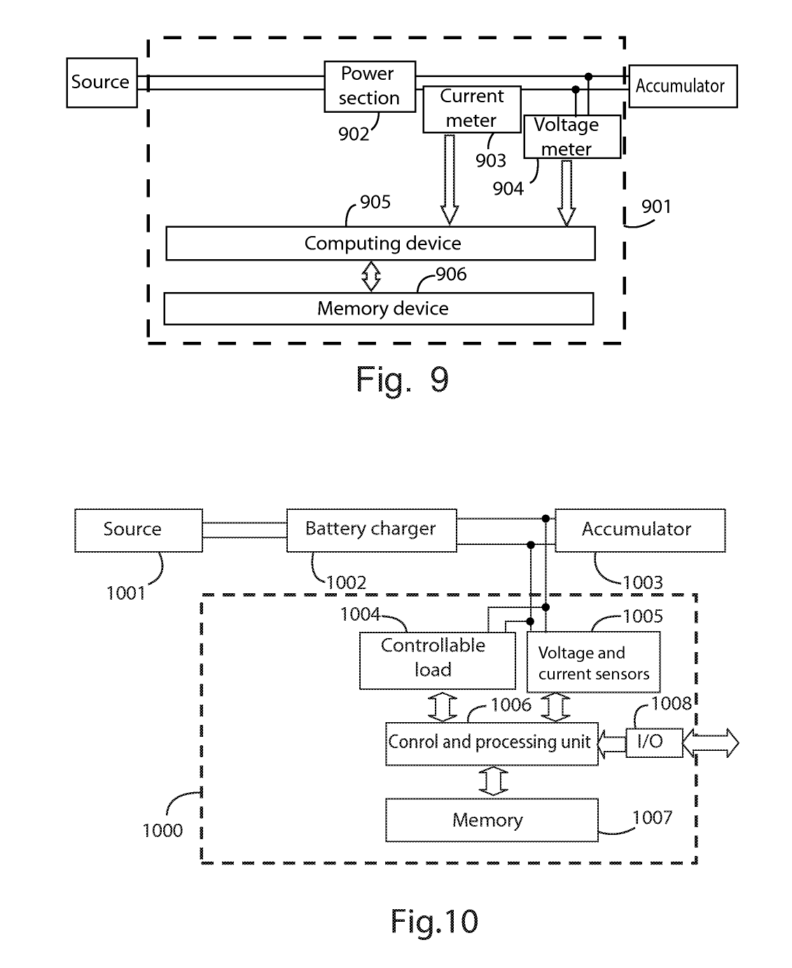

The proposed characterization method can be implemented by a dedicated charging system (FIG. 9), which represents a further aspect of the present disclosure. Such charging system 901 is provided with an input section and an output section and is able to obtain the energy from a source by the input section and provide it to the accumulator by the output section. In order to perform the above discussed characterization methods, the charging system comprises the following elements:
a power section 902, suitable to supply electric energy to the accumulator and to apply to the same accumulator a predetermined voltage and/or current waveform;
a measurement device 904 for measuring the voltage at the terminals of the accumulator;
a measurement device 903 for measuring the current flowing in the terminals of the accumulator;
a memory device 906;
a calculation device 905.

According to another aspect of the present disclosure, the proposed method can be performed by a control system to be used in addition to a conventional battery charger (FIG. 10). Such control system 1000 is based on the concept that it is possible to apply to the accumulator 1003 particular voltage and/or current waveforms during a standard charging process by absorbing a given portion of the current supplied by the battery charger.

In order to perform the proposed method, the proposed charging control system comprises two control terminals suitable to be connected, directly or by means of one or more devices in series, to the two terminals of the output section of the battery charger 1002, and by the presence of:
a load device 1004 that is able to absorb electric current by the above mentioned control terminals to the end of applying to the accumulator the current and/or voltage waveforms provided by the method;
a measurement device 1005 for measuring the voltage and the current at the terminals of the accumulator;
a memory device 1007;
a calculation device 1006.

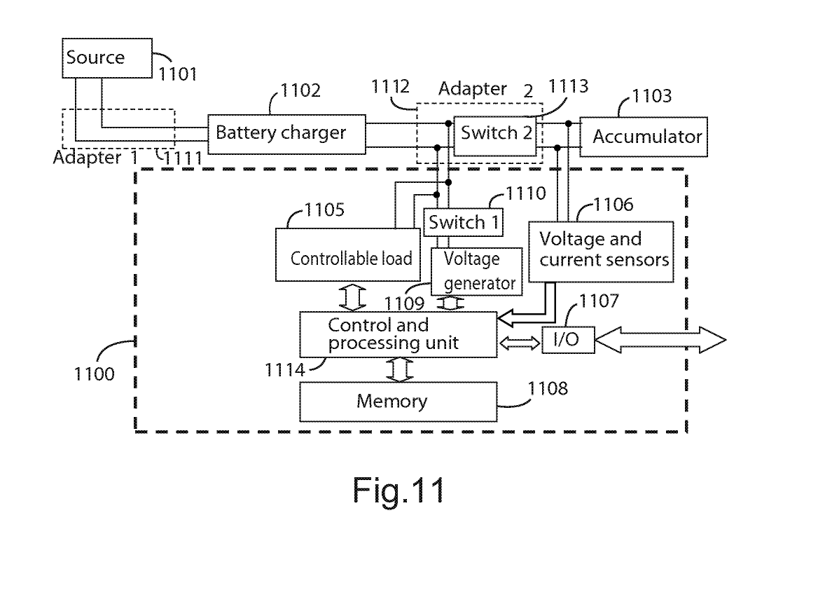

In another possible implementation (FIG. 11), the described charging control system can also comprise at least one switching block 1113 connected in series between the terminals of the output section of the battery charger 1102 and the terminals of the accumulator 1103, in order to electrically disconnect the accumulator and the battery charger during the time intervals wherein the load device absorbs current, and connecting them electrically in the remaining time intervals.

In some particular situations, the charging control system should be able to impose a predetermined voltage value between its control terminals. In such cases, a further embodiment of the charging control system can comprise the following additional elements:
a voltage generator device 1109 that is able to establish an electric potential difference between its two terminals, suitable to be electrically connected, directly or by means of one or more devices in series, to the terminals of the output section of the battery charger;
at least one switching block 1110 connected in series between the terminals of the voltage generator and the terminals of the output section of the battery charger, such switching block being configured in such a way to electrically connect the voltage generator and the battery charger during the time intervals where the load device absorbs current, and to disconnect them electrically in the remaining time intervals.

In another possible implementation, the proposed charging control system can further comprise a power section that is able to supply current by means of the control terminals of the same system.

In the foregoing, embodiments have been described and variations of the present invention have been suggested, but it is to be understood that those skilled in the art will be able to make changes and modifications without thereby falling outside the relevant scope of protection, as defined by the enclosed claims.

1. A method for characterization of electric parameters of an equivalent circuit of an accumulator as a function of its state of charge, comprising
a step A.1 of identification of an equivalent electric model of the accumulator,
a step A.2 of characterization of primary chemical reactions of the accumulator,
a step A.3 of characterization of secondary chemical reactions of the accumulator, and a step A.4 of calculation of electric parameters, said steps being as follows:
A.1) defining an equivalent electric circuit characterized by a set of electric parameters, said circuit comprising at least one primary branch including elements that during a charging process are traversed by current even in presence of only primary chemical reactions of the accumulator and to which primary branch respective primary parameters Pᵢ are associated, i being a positive integer, and at least one secondary branch including elements that during a charging process are traversed by current only in presence of secondary chemical reactions of the accumulator and to which secondary branch respective secondary parameters are associated;
A.2) characterizing the primary parameters Pᵢ of the primary branch, by repetitively executing, during an initial step of at least one accumulator charging process wherein the secondary reactions are negligible, whenever the accumulator state of charge is incremented of a pre-determined quantity obtained by a measurement of a state of charge during an overall accumulator charging process, the following sub-steps:
A.2.1) applying to the accumulator a pre-determined current and/or voltage waveform;
A.2.2) measuring, during a time interval, a pre-determined number of voltage values at the terminals of the accumulator and/or values of current flowing into the accumulator;
A.2.3) interpolating said voltage and/or current values measured in step A.2.2, determining an interpolating function reconstructing a time response of the voltage or current on the accumulator as a consequence of application of said waveform, and from said function obtaining the values of the electrical parameters of said at least one primary branch,
thus obtaining a set of values for each primary parameter Pᵢ, and executing subsequently the following sub-step:
A.2.4) for each primary parameter P, of said at least one primary branch, determining, by interpolation of said set of values, a function linking the value of the parameter to the generic increment of state of charge during the charging process when only the primary reactions are active;
A.3) characterizing the parameters of the at least one secondary branch, by repetitively executing, during time instants subsequent to said initial step of the at least one accumulator charging process, the following subsequent steps:
A.3.1) a testing step for testing presence of secondary reactions wherein, in a given instant, the voltage and current at the accumulator terminals are measured, and the presence of secondary reactions is determined if said voltage and current values deviate of a pre-determined quantity from the voltage and current values as calculated by means of the equivalent circuit of step A.1, assuming that the current absorbed in the at least one secondary branch vanishes and determining the parameters of the at least one primary branch by extrapolating the functions determined in step A.2.4, and storing: a first time instant t_{g} wherein the presence of secondary reaction is determined, current I_{B}(t_{g}) measured at the accumulator terminals at instant t_{g} and increment of state of charge ΔSOC(t_{g}) obtained from the beginning of the charging process up to time instant t_{g} as coming from the state of charge measurements of step A.2;
A.3.2) a sampling step wherein a pre-determined number of voltage and current values at the accumulator terminals in correspondence of time instants subsequent to said time instant t_{g} is stored;
A.4) determining, in any time instant subsequent to the end of said step A.3, mathematical functions allowing to calculate, for a hypothetical charging process, the primary electrical parameters Pᵢ of the accumulator in correspondence of any value of the state of charge both in absence and in presence of secondary reactions, performing the following sub-steps:
A.4.1) determining, on the basis of a value of the initial state of charge SOC₀ of said at least one charging process and the values of t_{g}, I_{B}(t_{g}) and ΔSOC(t_{g}) stored in step A.3.1, a function I_{acc}(SOC), linking the maximum current I_{acc} that can be absorbed by the at least one primary branch and the state of charge SOC, that satisfies the condition:
I_{ace}[SOC₀+ΔSOC(t_{g})]=I_{B}(t_{g})
A.4.2) determining, on the basis of the function I_{acc}(SOC) and the accumulator equivalent circuit, the values of the voltage and current at the terminals of the at least one secondary branch in correspondence of the values of voltage and current at the terminals of the accumulator stored in step A.3.2, and, by interpolating such values, determining a function V_{g}(I_{g}) expressing a relationship between voltage V_{g} and current I_{g} at the terminals of the at least one secondary branch;
A.4.3) determining mathematical functions connecting primary parameters Pᵢ and the state of charge both in absence and in presence of secondary reactions, performing for each primary parameter P, the following sub-steps:
A.4.3.1) determining, by interpolation of the values of said set of values of the parameters of step A.2, an interpolating function fₚᵢ(SOC), expressing a relationship between the primary parameter Pᵢ and the state of charge when only the primary reactions are active, and
A.4.3.2) determining a function fₛᵢ(SOC) expressing a relationship between the primary parameter Pᵢ and the state of charge when also the secondary reactions are active, said function coinciding with fₚᵢ(SOC) if the value of the primary parameter Pᵢ as a function of SOC is not influenced by the presence of secondary reactions, said function being otherwise determined by circuit analysis on the basis of the accumulator equivalent electric circuit of step A.1, the function I_{acc}(SOC), the function V_{g}(I_{g}) and the parameters whose function fₛᵢ(SOC) coincides with fₚᵢ(SOC).

2. The method according to claim 1, wherein the initial state of charge SOC₀ is not known before said at least one charging process, and in place of step A.4.1 the following step is executed:
A.4.1bis) determining the initial state of charge SOC₀ of said at least one charging process and a mathematical function I_{acc}(SOC) connecting the maximum current I_{acc} that can be absorbed by the at least one primary branch and the state of charge SOC, performing an iterative procedure comprising the following steps:
A.4.1.1) assuming a value of SOC₀;
A.4.1.2) on the basis of the assumed value of SOC₀ and the values of t_{g}, I_{B}(t_{g}) and ΔSOC(t_{g}) stored in step A.3.1, calculating a function I_{acc}(SOC) satisfying the condition:
I_{acc}[SOC₀+ΔSOC(t_{g})]=I_{B}(t_{g})
A.4.1.3) calculating the state of charge increment ΔSOC_{S} obtained by integrating the current I_{acc}, calculated according to the function determined in step A.4.1.2, from instant t_{g} up to a pre-determined instant of said at least one charging process of steps A.2 and A.3, and calculating the state of charge SOC_{f} of the charging process in said pre-determined instant, estimated on the basis of the following relationship:
SOC_{f}=SOC₀+ΔSOC(t_{g})+ΔSOC_{S}
A.4.1.4) calculating a difference between the state of charge actually achieved in said pre-determined instant of said at least one charging process and the state of charge SOC_{f} estimated in step A.4.1.3;
A.4.1.5) if the difference calculated in step A.4.1.4 exceeds a pre-determined quantity, increasing the assumed value of SOC₀ by a quantity that is function of said difference, in particular proportional to said difference, and repeating steps A.4.1.2-A.4.1.5, otherwise terminating the iterative procedure.

3. The method according to claim 1, wherein for a pre-determined number of repetitions of step A.2.2 a first group of measurements is performed wherein:
the duration of the time interval wherein each measurement is performed is such to allow the measurement of all the parameters of said at least one primary branch, and wherein the measured parameters values are also used to define mathematical functions expressing a subset of the parameters of said at least one primary branch as a function of a different subset of the parameters of said at least one primary branch assumed as set of reference parameters;
and wherein the remaining repetitions of step A.2.2 comprise a second group of measurements, wherein:
the duration of the time interval is such to allow only measurement of said reference parameters, and wherein the values of the remaining parameters of said at least one primary branch are obtained from the values of said reference parameters by extrapolation using the functions calculated during the first group of measurements.

4. The method according to claim 1, wherein function I_{acc}(SOC) is:
$${I}_{acc} = \frac{{A}_{0}}{1 - {SOC}_{i}} ( \frac{1}{SOC} - 1 ) ,$$
SOCᵢ being the initial state of charge of said hypothetical charging process, and A₀ being a real value constant coefficient, determined in step A.4.1.

5. The method according to claim 2, wherein function I_{acc}(SOC) is:
$${I}_{acc} = \frac{{A}_{0}}{1 - {SOC}_{i}} ( \frac{1}{SOC} - 1 ) ,$$
SOCᵢ being the initial state of charge of said hypothetical charging process, and A₀ being a real value constant coefficient, determined in step A.4.1 bis.

6. The method according to claim 1, wherein function V_{g}(I_{g}) determined in step A.4.2 is:
$${V}_{g} = {V}_{g 0} + {a}_{1} \frac{{I}_{Bref}}{{I}_{B}} {I}_{g} + {{a}_{2} ( \frac{{I}_{Bref}}{{I}_{B}} )}^{2} {I}_{g}^{2} ,$$
during the time intervals of the process wherein the charging process is at constant current, i.e. wherein the charging system connected to the accumulator behaves as a current generator, I_{Bref} being a generic value of the current flowing through the accumulator terminals that is taken as a reference value, V_{g0}, a₁ and a₂ being real value constant coefficients determined by interpolation of at least three values of I_{g} and V_{g} obtained in step A.4.2, and function V_{g}(I_{g}) is of the type
$${V}_{g} = \frac{{I}_{g} - {q}_{g}}{{m}_{g}} ,$$
during the time intervals of the process wherein the charging process is at constant voltage, i.e. wherein the charging system connected to the accumulator behaves as a voltage generator, q_{g} and m_{g} being two real-value coefficients whose value takes into account the voltage applied to the accumulator during the specific time interval where the charging process is at constant voltage.

7. The method according to claim 1, wherein the at least one primary branch of the accumulator equivalent circuit of step A.1 comprises a determined number of resistors and at least one voltage generator whose value V_{OC} models the open-circuit voltage of the accumulator.

8. The method according to claim 7, wherein, for each resistor belonging to the at least one primary branch of the accumulator equivalent circuit, the function fₚᵢ(SOC) determined in step A.4.3.1 is:
fₚᵢ=αm_{Ri0}(SOC−SOCᵢ)+Rᵢ₀,
SOCᵢ being the initial state of charge of said hypothetical charging process, m_{Ri0} and Rᵢ₀ being real-value constant coefficients determined by means of interpolation of at least two values of said resistor as measured in step A.2, and α being a coefficient whose value is determined each time for each charging process according to the relationship:
$$α = \frac{1}{{m}_{Ri 0}} \frac{{f}_{si} ( SOC ( {t}_{g} ) ) - {R}_{i 0}}{SOC ( {t}_{g} ) - {SOC}_{i}} ,$$
wherein t_{g} is the instant at which the secondary reactions start, determined as the instant at which the current I_{acc} equals the current I_{B} flowing through the accumulator terminals, SOC(t_{g}) is the value of the state of charge calculated at t_{g}, and fₛᵢ(SOC(t_{g})) is the value of the function fₛᵢ(SOC), as determined in step A.4.3.2, calculated in correspondence of said value of SOC(t_{g}).

9. The method according to claim 7, wherein function fₚᵢ(SOC) as determined in step A.4.3.1 and function fₛᵢ(SOC) as determined in step A.4.3.2 for the voltage generator of value V_{OC} coincide and are of the type:
fₚᵢ(SOC)=fₛᵢ(SOC)=m_{V}SOC+q_{V},
mᵥ and qᵥ being real-value constant coefficients determined by interpolation of at least two values of V_{OC} determined in step A.2.

10. The method according to claim 1, wherein steps A.2 and A.3 are performed in correspondence of a given number of accumulator working temperature T in order to characterize the parameters of the accumulator equivalent circuit even as a function of the working temperature, determining in step A.4, by interpolation of the measured values:
a function I_{acc}(SOC, T) expressing the relationship between the maximum current that can be absorbed by the at least one primary branch and any values pair (SOC,T), and a function V_{g}(I_{g}, T) expressing the relationship between the voltage at the terminals of the at least one secondary branch and any values pair (I_{g}, T),
and, for each parameter of the at least one primary branch, determining:
a function fₚᵢ(SOC, T), each time different depending on the parameter Pᵢ, that expresses the relationship between the parameter and any values pair (SOC,T) when only the primary reactions are active, and a function fₛᵢ(SOC,T), each time different depending on the parameter Pᵢ, expressing the relationship between the parameter and any values pair (SOC,T) when also the secondary reactions are active, such a function fₛᵢ(SOC,T) coinciding with fₚᵢ(SOC,T) if the value of the parameter as a function of (SOC,T) is not influenced by the presence of secondary reactions, otherwise being determined by circuit analysis on the basis of the accumulator equivalent circuit, the functions I_{acc}(SOC,T), V_{g}(I_{g}, T) and the parameters whose function fₛᵢ(SOC,T) coincides with fₚᵢ(SOC,T).

11. A charging system for electric energy accumulators, such a system provided with an input section and an output section and being able to take energy from a source by the input section and to give energy to the accumulator by the output section, the system comprising the following elements:
a power section, suitable to provide electric energy to the accumulator and to apply to the same accumulator pre-determined voltage and/or current waveforms,
a voltage measurement device for measuring voltage at the terminals of the accumulator,
a current measurement device for measuring current flowing into the terminals of the accumulator,
a memory device, and
an electronic calculation device,
said system being suitable to perform any charging process of the accumulator and the method of characterization of the electric parameters of the electric equivalent circuit according to claim 1, wherein:
said power section is configured to apply to the accumulator a current and/or voltage waveform according to step A.2.1;
said voltage measurement device and said current measurement device are configured to perform the measurements of steps A.2.2, A.3.1, A.3.2;
said calculation device performs the calculations of steps A.2, A.3 and A.4;
said memory device is used to store the data calculated by the method.

12. A charge control system for an electric energy accumulator receiving energy from an external battery charger, which includes an input section and an output section and is able to take energy from a source by the input section and to give energy to the accumulator by the output section having two terminals, said charge control system comprising two control terminals suitable to be connected, directly or by means of one or more devices in series, at the two terminals of said output section of the battery charger, said charge control system further comprising:
a load device suitable to absorb electric current by said two control terminals;
a voltage measurement device for measuring the voltage at the terminals of the accumulator;
a current measurement device for measuring the current flowing into the accumulator terminals,
a memory device, and
a calculation device,
said system being suitable to execute the method of characterization of the electrical parameters of the accumulator electric equivalent circuit according to claim 1, wherein:
said load device is configured to absorb electric current by said two control terminals during pre-defined time intervals in such a way that a pre-defined current and/or voltage waveform is applied to the accumulator, according to step A.2.1;
said voltage measurement device and said current measurement device are configured to perform the measurements of steps A.2.2, A.3.1, A.3.2;
said calculation device performs the calculations of steps A.2, A.3 and A.4;
said memory device is configured to store the data calculated in the method.

13. The charge control system according to claim 12, further comprising at least one switching block connected in series between the terminals of the output section of the battery charger and the accumulator terminals, such a switching block being configured in such a way to electrically disconnect the accumulator from the output section of the battery charger during the time intervals wherein the load device absorb current, and to electrically connect the accumulator to the output section of the battery charger in the remaining time intervals, said system further comprising the following elements:
a voltage generator provided with two terminals suitable to be electrically connected, directly or by one or more devices in series, to the terminals of the output section of the battery charger, said voltage generator being suitable to establish a voltage difference between its terminals;
at least one switching block connected in series between the terminals of said voltage generator and the terminals of the output section of the battery charger, such switching block being configured in such a way to electrically connect the voltage generator to the output section of the battery charger during the time intervals wherein the load device absorbs current, and to electrically disconnect the voltage generator from the output section of the battery charger in the remaining time intervals.

14. The charge control system according to claim 12, further comprising a power section suitable to supply current by said two control terminals.

15. A computer device comprising a processor, the processor configured to execute instructions of a computer program that performs the calculations of steps A.2, A.3 and A.4 of the method according to claim 1.

16. A non-transitory memory support, storing a computer program that performs, when executed on a computer, the calculations of steps A.2, A.3 and A.4 of the method according to claim 1.
